(19) United States
(12) Patent Application Publication
(10) Pub. No.: US 2024/0154054 A1
(43) Pub. Date: May 9, 2024

(54) OPTOCOUPLER

(71) Applicant: Taiwan-Asia Semiconductor Corporation, Hsinchu City (TW)

(72) Inventor: Di-Bao WANG, Hsinchu City (TW)

(21) Appl. No.: 18/489,562

(22) Filed: Oct. 18, 2023

(30) Foreign Application Priority Data
Nov. 7, 2022 (TW) 111142465

(51) Int. Cl. H01L 31/173; H01L 31/0203; H01L 31/0232; H01L 31/0304

(52) U.S. Cl. CPC H01L 31/173; H01L 31/0203; H01L 31/02325; H01L 31/03044

(57) ABSTRACT

The present invention provides an optocoupler, including a substrate, a gallium nitride light emitter, a gallium nitride light sensing switch, a reflective structure and a transmission medium. The gallium nitride light emitter and the gallium nitride light sensing switch are disposed on the substrate and electrically isolated from each other. The gallium nitride light emitter is used for emitting a light signal according to an input signal. The gallium nitride light sensing switch is used for sensing the light signal and generating an output signal accordingly. The reflective structure is used for reflecting the light signal. The transmission medium is at least between the gallium nitride light emitter, the gallium nitride light sensing switch and the reflective structure. The light signal from the gallium nitride light emitter is transmitted in the transmission medium and transmitted obliquely to the gallium nitride light sensing switch after being reflected by the reflective structure.

### CROSS-REFERENCES TO RELATED APPLICATIONS

This application claims priority to Taiwan Patent Application No. 111142465 filed on Nov. 7, 2022, which is hereby incorporated by reference in its entirety.

### BACKGROUND OF THE INVENTION

### Field of the Invention

The present invention relates to an optocoupler, especially an optocoupler whose main material is gallium nitride.

### Descriptions of the Related Art

Generally, for signal transmission between different devices with large power supply voltage differences, it is necessary to use a coupler or isolator to provide electrical isolation and act as a medium for performing signal transmission. Commonly used couplers include optical couplers (i.e., optocouplers) or electromagnetic couplers (i.e., digital couplers). The optocoupler uses light emitting diodes as light sources, and uses corresponding photosensitive devices to achieve electrical-optical-electrical signal conversion and transmission. However, most of the conventional optocouplers are made of silicon material and require two chips for manufacturing the light-emitting and light-receiving parts, respectively, resulting in more complications and higher costs in the process. In addition, the switching frequency of conventional optocouplers is limited, and it is necessary to add additional circuits to barely increase the switching frequency from 1 MBd to 10 MBd, so many restrictions are in use.

The electromagnetic coupler utilizes various adjacent electromagnetic induction devices to achieve electrical-electromagnetic wave-electrical signal conversion transmission, in which the switching frequency of the electromagnetic coupler can be higher than 25 MBd, and has low power consumption. However, due to the use of electromagnetic waves, the electromagnetic coupler easily causes electromagnetic interference or is susceptible to electromagnetic interference, resulting in troubles in use. In addition, the electromagnetic coupler requires an additional modulation/demodulation circuit, which occupies a certain area of the overall chip and causes additional power consumption.

Therefore, it is worthwhile to study how to design an optocoupler that can resolve the aforementioned problems.

### SUMMARY OF THE INVENTION

The objective of the present invention is to provide an optocoupler whose main material is gallium nitride.

To achieve the above objective, the optocoupler of the present invention includes a substrate, a gallium nitride light emitter, a gallium nitride light sensing switch, a reflective structure and a transmission medium. The gallium nitride light emitter and the gallium nitride light sensing switch are disposed on the substrate and electrically isolated from each other. The gallium nitride light emitter is configured to emit a light signal according to an input signal. The gallium nitride light sensing switch is configured to sense the light signal and generate an output signal accordingly. The reflective structure is configured to reflect the light signal. The transmission medium is at least between the gallium nitride light emitter, the gallium nitride light sensing switch and the reflective structure. The light signal from the gallium nitride light emitter is transmitted in the transmission medium and transmitted obliquely to the gallium nitride light sensing switch after being reflected by the reflective structure.

In an embodiment of the present invention, the gallium nitride light emitter comprises at least one LED structure or at least one light emitting high electron mobility transistor structure.

In an embodiment of the present invention, the gallium nitride light emitter includes a first LED structure and a second LED structure, the first LED structure and the second LED structure are connected in anti-parallel to each other, and the input signal is an alternating current (AC) signal.

In an embodiment of the present invention, the gallium nitride light sensing switch comprises at least one BJT structure or at least one high electron mobility transistor structure.

In an embodiment of the present invention, the gallium nitride light sensing switch includes a first BJT structure and a second BJT structure, and the first BJT structure and the second BJT structure are connected in series to each other to amplify the output signal.

In an embodiment of the present invention, the transmission medium at least partially covers the gallium nitride light emitter and the gallium nitride light sensing switch, and the reflective structure is disposed on the transmission medium.

In an embodiment of the present invention, the transmission medium is made of a packaging material or an insulating material having light transmission characteristics.

In an embodiment of the present invention, the transmission medium is SiO₂, Si₃N₄ or epoxy resin.

In an embodiment of the present invention, the optocoupler includes a peripheral packaging structure, at least packaging the gallium nitride light emitter, the gallium nitride light sensing switch and the transmission medium, wherein the reflective structure is disposed on an inner surface of the peripheral packaging structure facing the gallium nitride light emitter and the gallium nitride light sensing switch.

In an embodiment of the present invention, the transmission medium is air.

In an embodiment of the present invention, the light signal emitted by the gallium nitride light emitter has a wavelength ranging between 300 nm and 500 nm.

In an embodiment of the present invention, the substrate is a silicon substrate or a sapphire substrate.

In an embodiment of the present invention, the optocoupler further includes a plurality of buffer layers, wherein when the substrate is the silicon substrate, the plurality of buffer layers are disposed between the gallium nitride light emitter and the substrate and between the gallium nitride light sensing switch and the substrate.

Accordingly, in the optocoupler of the present invention, the light emitter and the light sensing switch made of gallium nitride are disposed on the same substrate, and they are electrically isolated therebetween without the need for additional modulation circuits, thereby reducing the overall chip area, simplifying the manufacturing process, reducing cost, and allowing signal switching frequency to be increased. In addition, the optocoupler of the present invention mainly transmits signals effectively by the reflection of oblique light, and does not cause problems such as electromagnetic interference.

### BRIEF DESCRIPTION OF THE DRAWINGS

FIG. 1A is a schematic view of an optocoupler of the present invention.

FIG. 1B is a circuit block diagram of the optocoupler of the present invention.

FIG. 2 is a schematic view of the first embodiment of the optocoupler of the present invention.

FIG. 3 is a schematic view of the second embodiment of the optocoupler of the present invention.

FIG. 4 is a schematic view of the third embodiment of the optocoupler of the present invention.

FIG. 5 is a schematic view of the fourth embodiment of an optocoupler of the present invention.

FIG. 6 is a schematic view of the fifth embodiment of the optocoupler of the present invention.

FIG. 7A is a schematic view of the sixth embodiment of the optocoupler of the present invention.

FIG. 7B is another schematic view of the sixth embodiment of the optocoupler of the present invention.

FIG. 8A is a schematic view of the seventh embodiment of the optocoupler of the present invention.

FIG. 8B is another schematic view of the seventh embodiment of the optocoupler of the present invention.

### DETAILED DESCRIPTION OF THE PREFERRED EMBODIMENT

Since the various aspects and embodiments are merely illustrative and not restrictive, after reading this specification, there may also be other aspects and embodiments without departing from the scope of the present invention to a person having ordinary skill in the art. The features and advantages of these embodiments and the scope of the patent application will be better appreciated from the following detailed description.

Herein, “a” or “an” is used to describe one or more devices and components described herein. Such a descriptive term is merely for the convenience of illustration and to provide a general sense of the scope of the present invention. Therefore, unless expressly stated otherwise, the term “a” or “an” is to be understood to include one or at least one, and the singular form also includes the plural form.

Herein, the terms “first” or “second” and similar ordinal numbers are mainly used to distinguish or refer to the same or similar devices or structures, and do not necessarily imply the spatial or temporal order of such devices or structures. It should be understood that in certain situations or configurations, ordinal numbers may be used interchangeably without affecting the practice of the present invention.

As used herein, the term “comprise” “include,” “have” or any other similar term is not intended to exclude additional, unrecited elements. For example, a device or structure comprising/including/having a plurality of elements is not limited to the elements listed herein but may comprise/include/have other elements not explicitly listed but generally inherent to the device or structure.

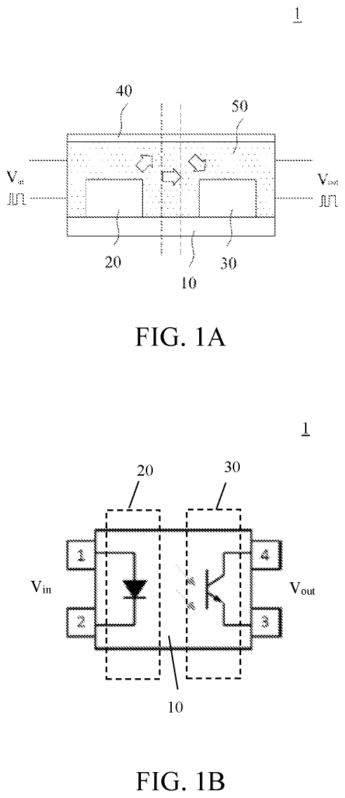

Please refer to FIG. 1A and FIG. 1B together. FIG. 1A is a schematic view of the optocoupler of the present invention, and FIG. 1B is a circuit block diagram of the optocoupler of the present invention. As shown in FIG. 1A and FIG. 1B, the optocoupler 1 of the present invention mainly includes a substrate 10, a gallium nitride light emitter 20, a gallium nitride light sensing switch 30, a reflective structure 40 and a transmission medium 50. The substrate 10 is mainly used as a basic structural member for allowing circuit elements and/or material layers of the optocoupler 1 of the present invention to be arranged thereon. In the present invention, the substrate 10 may be an undoped silicon substrate or a sapphire substrate, but the material of the substrate 10 may be changed according to different design requirements.

The gallium nitride light emitter 20 is disposed on the substrate 10, and the gallium nitride light emitter 20 is made of gallium nitride as a main semiconductor material. The gallium nitride light emitter 20 is used for receiving an input signal Vᵢₙ, and emitting a light signal according to the input signal Vᵢₙ. In the present invention, the gallium nitride light emitter 20 includes at least one light emitting diode (LED) structure or at least one light emitting high electron mobility transistor (LE-HEMT) structure, and at least one LED structure or at least one LE-HEMT structure used therein varies according to different design requirements. In one embodiment of the present invention, the wavelength of the light signal emitted by the gallium nitride light emitter 20 ranges between 300 nm and 500 nm, that is to say, the light signal is roughly in the range from ultraviolet light to blue light, but the present invention is not limited thereto.

The gallium nitride light sensing switch 30 is disposed on the substrate 10, and the gallium nitride light sensing switch 30 is made of gallium nitride as a main semiconductor material. The gallium nitride light sensing switch 30 is used to sense the light signal emitted by the gallium nitride light emitter 20, and generate a corresponding sensing signal according to the light signal, and then generate an output signal Vₒᵤₜ. In other words, the gallium nitride light sensing switch 30 is capable of simultaneously providing the sensing function of the light signal and the switching function of generating the output signal Vₒᵤₜ. In the present invention, the gallium nitride light sensing switch 30 includes at least one bipolar junction transistor (BJT) structure or at least one high electron mobility transistor (HEMT) structure, and the number of at least one BJT structure or at least one HEMT structure used therein varies according to different design requirements. The gallium nitride light emitter 20 is designed to be electrically isolated from the gallium nitride light sensing switch 30 (the area separated by the dotted line in FIG. 1A, in which the electrical isolation can be achieved by structural design and/or materials).

The reflective structure 40 is used for reflecting the light signal emitted by the gallium nitride light emitter 20 to the gallium nitride light sensing switch 30. The reflective structure 40 is mainly disposed on the transmission path of the light signal. In the present invention, the reflective structure 40 is made of aluminum or expanded polytetrafluoroethylene (e-PTFE).

The transmission medium 50 is at least between the gallium nitride light emitter 20, the gallium nitride light sensing switch 30 and the reflective structure 40. The transmission medium 50 at least partially covers the gallium nitride light emitter 20 and the gallium nitride light sensing switch 30 so that the aforementioned light signal can be transmitted in the transmission medium 50. In the present invention, the transmission medium 50 may be made of a packaging material or an insulating material having light transmission characteristics. Therefore, the transmission medium 50 can provide the effects of light transmission and chip packaging and/or electrical isolation. The aforementioned packaging material is a high molecular compound material, such as epoxy resin, but the packaging material may also be replaced by other high molecular compound materials. The aforementioned insulating material may be SiO₂ or Si₃N₄. In an embodiment of the present invention, the transmission medium 50 may also be air or other mediums, which may be changed according to different design requirements. In addition, in an embodiment of the present invention, when the transmission medium 50 is solid, the reflective structure 40 may be disposed on the transmission medium 50.

The optocoupler 1 of the present invention can convert the received input signal Vᵢₙ into an output signal Vₒᵤₜ, and the input signal Vᵢₙ and the output signal Vₒᵤₜ have the same or opposite phase waveforms. In the present invention, the input signal Vᵢₙ may be a voltage signal obtained from a high voltage area, and the output signal Vₒᵤₜ may be a voltage signal supplied to a low voltage area, but the present invention is not limited thereto. For example, Vᵢₙ may be a voltage signal obtained from the low voltage area, and Vₒᵤₜ may be a voltage signal obtained from the high voltage area. Therefore, the optocoupler 1 of the present invention can be adopted to effectively achieve the signal transmission effect between the high voltage area and the low voltage area through light transmission.

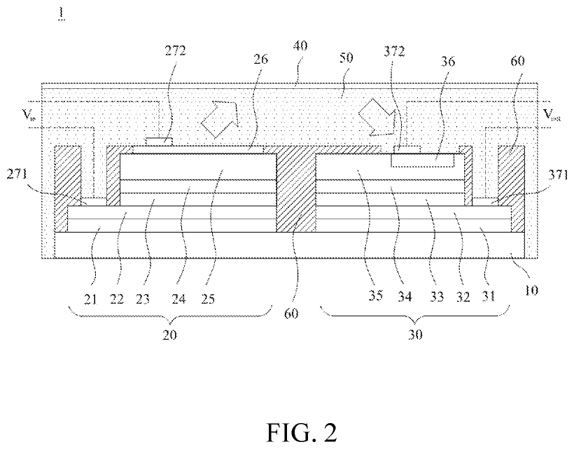

The detailed structure and circuit configuration of various embodiments of the optocoupler of the present invention will be further described below. Reference is made to FIG. 2, which is a schematic view of the first embodiment of the optocoupler of the present invention. As shown in FIG. 2, in the present invention, the main structures of the gallium nitride light emitter 20 and the gallium nitride light sensing switch 30 may be formed on the substrate 10 by a metal organic chemical vapor deposition (MOCVD) process. In this embodiment, the substrate 10 of the optocoupler 1 of the present invention is an undoped sapphire substrate. The gallium nitride light emitter 20 includes an undoped gallium nitride layer 21, an N-type gallium nitride layer 22, an intrinsic indium gallium nitride/gallium nitride active layer 23, a P-type gallium nitride/aluminum gallium nitride layer 24, a P-type gallium nitride layer 25 and a transparent electrode 26 in order from the side of the substrate 10. The N-type gallium nitride layer 22 and the transparent electrode 26 can be electrically connected to external devices through the electrical contacts 271 and 272, respectively, so as to receive the input signal Vᵢₙ. The transparent electrode 26 may be made of indium tin oxide (ITO) or other similar materials, and the electrical contacts 271, 272 may be made of titanium or aluminum. The gallium nitride light emitter 20 may form an LED structure by the aforementioned multilayer structure, wherein the light signal is generated by the intrinsic indium gallium nitride/gallium nitride active layer 23 and emitted through the transparent electrode 26.

The gallium nitride light sensing switch 30 includes an undoped gallium nitride layer 31, a first N-type gallium nitride layer 32, an intrinsic indium gallium nitride/gallium nitride active layer 33, a P-type gallium nitride/aluminum gallium nitride layer 34, a P-type gallium nitride layer 35 and a second N-type gallium nitride layer 36 in order from the side of the substrate 10. The first N-type gallium nitride layer 32 and the second N-type gallium nitride layer 36 may be electrically connected to external devices through electrical contacts 371 and 372, respectively, to transmit the output signal Vₒᵤₜ. The electrical contacts 371, 372 may be made of titanium or aluminum. The gallium nitride light sensing switch 30 may be formed into a BJT structure by the aforementioned multilayer structure, wherein the P-type gallium nitride layer 35 acts as the base to receive light signals, the first N-type gallium nitride layer 32 acts as the collector, and the second N-type gallium nitride layer 36 acts as the emitter. In the present invention, the same material layers for constituting the aforementioned gallium nitride light emitter 20 and gallium nitride light sensing switch 30 all may be formed using the same MOCVD process (e.g., the undoped gallium nitride layers 21 and 31, the N-type gallium nitride layer 22 and the first N-type gallium nitride layer 32, and the like) to simplify the process steps of the optocoupler 1 of the present invention.

The isolation layer 60 is formed on the substrate 10. The isolation layer 60 at least partially covers the gallium nitride light emitter 20 and the gallium nitride light sensing switch 30. By being separated by the isolation layer 60, the gallium nitride photo-transmitter 20 and the gallium nitride light sensing switch 30 are electrically isolated from each other. In this embodiment, the isolation layer 60 may be composed of SiO₂ or Si₃N₄, but the present invention is not limited thereto. In addition, in the process of the optocoupler 1 of the present invention, the transparent electrode 26 and the electrical contacts 271, 272 of the aforementioned gallium nitride light emitter 20, a partial area of the P-type gallium nitride layer 35 of the gallium nitride light sensing switch 30, the second N-type gallium nitride layer 36 and the electrical contacts 371, 372 may be exposed outside the isolation layer 60, so as to facilitate the light signal transmission and/or the electrical connection with corresponding devices or power sources.

In this embodiment, by the packaging process, the packaging material (e.g., epoxy resin) may be used to cover the entire substrate 10 and to cover the gallium nitride light emitter 20 and the gallium nitride light sensing switch 30 disposed on the substrate 10 to form an entire packaging structure used as the transmission medium 50. The reflective structure 40 may be disposed on the transmission medium 50. Therefore, the light signal emitted from the gallium nitride light emitter 20 can be transmitted in the transmission medium 50, reflected by the reflective structure 40, and transmitted obliquely to the gallium nitride light sensing switch 30. In a preferred embodiment of the present invention, the wavelength of the light signal emitted by the gallium nitride light emitter 20 is restricted to 400 nm to 500 nm, i.e., approximately in the range of blue light, in order to avoid material cracking due to the transmission medium 50 being irradiated with ultraviolet light, but the present invention is not limited thereto. Accordingly, the components of the optocoupler 1 of the present invention may be integrated on a single substrate 10 to form a single chip structure, thereby simplifying the complexity of the process and reducing the size of the chip. The optocoupler 1 of the present invention combines light sensing and switching functions through the gallium nitride light sensing switch 30, and without the need to set up additional circuits, the switching rate can be increased up to 20-50 MBd, which provides a better signal transmission effect.

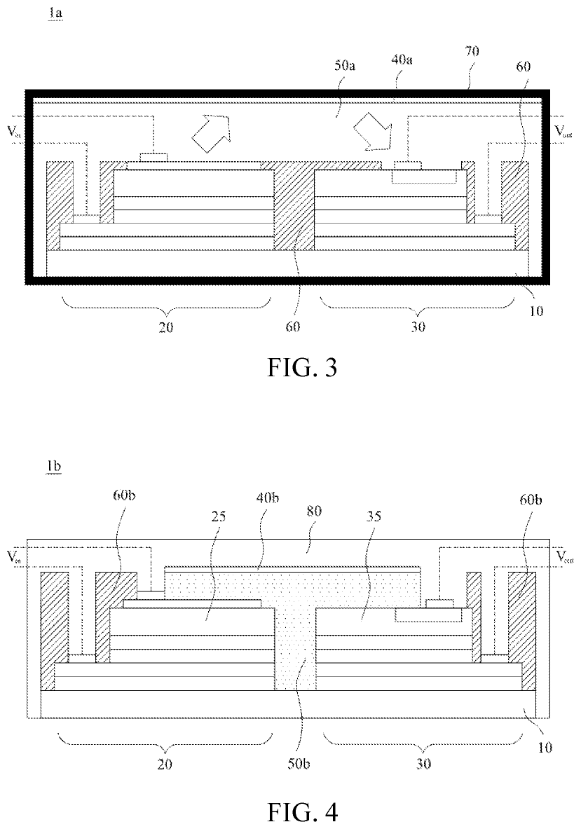

Please refer to FIG. 3, which is a schematic view of the second embodiment of the optocoupler of the present invention. This embodiment is a structural modification of the above first embodiment, and the difference lies in the change in the transmission medium and the packaging structure. As shown in FIG. 3, in this embodiment, the optocoupler 1a of the present invention further includes a peripheral packaging structure 70. The peripheral packaging structure 70 is a hollow shell, and at least the substrate 10, the gallium nitride light emitter 20, the gallium nitride light sensing switch 30 and the transmission medium 50a are packaged and fixed inside by the peripheral packaging structure 70. The reflective structure 40a is disposed on the inner surface of the peripheral packaging structure 70 facing the gallium nitride light emitter 20 and the gallium nitride light sensing switch 30. Air is filled between the gallium nitride light emitter 20, the gallium nitride light sensing switch 30 and the reflective structure 40a as the transmission medium 50a. Therefore, the light signal emitted from the gallium nitride light emitter 20 can also be transmitted in the transmission medium 50a, reflected by the reflective structure 40a and transmitted obliquely to the gallium nitride light sensing switch 30. Since the air does not have the problem of material cracking due to irradiation by ultraviolet light, in this embodiment, the wavelength of the light signal emitted by the gallium nitride light emitter 20 can range between 300 nm and 500 nm, i.e., the light signal can cover the range of ultraviolet light, but the present invention is not limited thereto.

Reference is made to FIG. 4, which is a schematic view of the third embodiment of the optocoupler of the present invention. This embodiment is a structural modification of the above first embodiment, and the difference lies in the changes in the reflective structure, the transmission medium and the packaging structure. As shown in FIG. 4, in this embodiment, the optocoupler 1b of the present invention uses an isolation layer 60b (i.e., an insulating material) as the transmission medium 50b. By increasing the thickness of the isolation layer 60b, the top surface of the isolation layer 60b has an appropriate distance from the P-type gallium nitride layer 25 of the gallium nitride light emitter 20 and the P-type gallium nitride layer 35 of the gallium nitride light sensing switch 30 so as to allow the light signal transmission. In an embodiment of the present invention, the aforementioned appropriate spacing is about 3 μm to 10 μm, but the present invention is not limited thereto. The reflective structure 40b is disposed on the top surface of the isolation layer 60b. In order to prevent the reflective structure 40b from being easily electrically contacted with the transparent electrode 26 or the electrical contact 27 due to the aforementioned appropriate spacing being too small, the reflective structure 40b herein is made of e-PTFE. The packaging structure 80 may be made of epoxy resin or ceramic material. Therefore, the light signal emitted from the gallium nitride light emitter 20 can also be transmitted in the transmission medium 50b, and then transmitted obliquely to the gallium nitride light sensing switch 30 after being reflected by the reflective structure 40b.

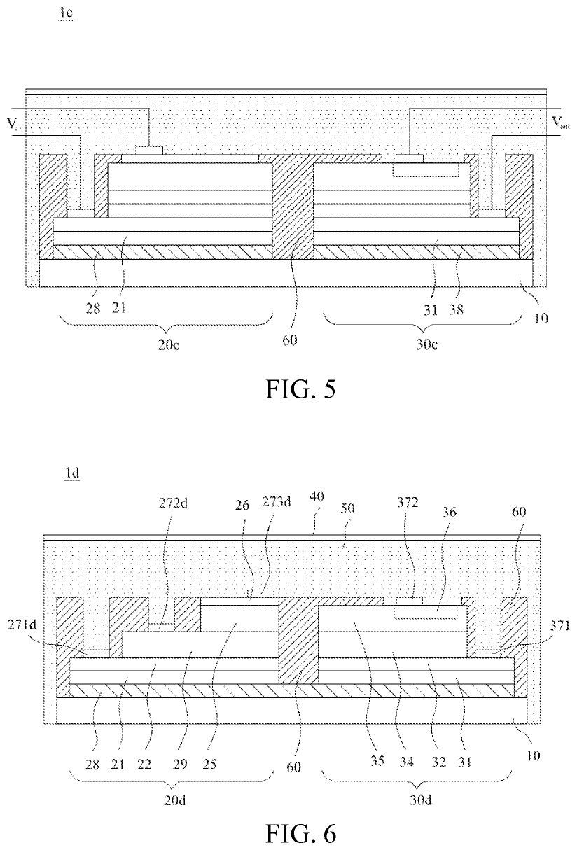

Please refer to FIG. 5, which is a schematic view of the fourth embodiment of the optocoupler of the present invention. This embodiment is a structural modification of the above first embodiment, and the difference lies in the configuration of multiple buffer layers. As shown in FIG. 5, in this embodiment, the optocoupler 1c of the present invention further includes a plurality of buffer layers 28, 38. When the substrate 10 is a silicon substrate, the plurality of buffer layers 28, 38 are disposed between the undoped gallium nitride layer 21 of the gallium nitride light emitter 20c and the substrate 10 and between the undoped gallium nitride layer 31 of the gallium nitride light sensing switch 30c and the substrate 10, respectively. The buffer layers 28 and 38 may be made of aluminum nitride, aluminum gallium nitride or silicon carbide. With the configuration of the plurality of buffer layers 28, 38, it is easier to form the epitaxial effect of each semiconductor layer by performing the aforementioned MOCVD process on the silicon substrate. The technical means with respect to the configuration of the above-mentioned silicon substrate and the buffer layer can also be applied to the above-mentioned second embodiment or third embodiment instead of using the sapphire substrate, and it will not be further described herein.

Reference is made to FIG. 6, which is a schematic view of the fifth embodiment of the optocoupler of the present invention. This embodiment is a structural modification of the above first embodiment, and the difference lies in the changes in the structural configuration of the gallium nitride light emitter 20d and the gallium nitride light sensing switch 30d. As shown in FIG. 6, in this embodiment, the substrate 10 of the optocoupler 1d of the present invention is an undoped silicon substrate. The gallium nitride light emitter 20d includes a buffer layer 28, an undoped gallium nitride layer 21, an N-type gallium nitride layer 22, an aluminum gallium nitride layer 29, a P-type gallium nitride layer 25 and a transparent electrode 26 in order from the side of the substrate 10. The N-type gallium nitride layer 22, the aluminum gallium nitride layer 29 and the transparent electrode 26 may be provided with electrical contacts 271d, 272d and 273d, respectively. The transparent electrode 26 may be made of indium tin oxide or other similar materials, and the electrical contacts 271d, 272d and 273d may be made of titanium or aluminum. The gallium nitride light emitter 20d may be formed into a LE-HEMT structure by the aforementioned multilayer structure, wherein the electrical contact 271d acts as the source, the electrical contact 272d acts as the gate, and the electrical contact 273d acts as the drain to generate a light signal by the aluminum gallium nitride layer 29 and emit it through the transparent electrode 26.

The gallium nitride light sensing switch 30d includes a buffer layer 28, an undoped gallium nitride layer 31, a first N-type gallium nitride layer 32, a P-type gallium nitride/aluminum gallium nitride layer 34, a P-type gallium nitride layer 35 and a second N-type gallium nitride layer 36 in order from the side of the substrate 10. The first N-type gallium nitride layer 32 and the second N-type gallium nitride layer 36 may be provided with electrical contacts 371 and 372, respectively. The electrical contacts 371, 372 may be made of titanium or aluminum. The gallium nitride light sensing switch 30d may be formed into a BJT structure by the aforementioned multilayer structure, wherein the P-type gallium nitride layer 35 acts as the base to receive light signals, the first N-type gallium nitride layer 32 acts as the collector, and the second N-type gallium nitride layer 36 acts as the emitter. Similarly, the same material layers for constituting the aforementioned gallium nitride light emitter 20d and the gallium nitride light sensing switch 30d all may be formed using the same MOCVD process to simplify the process steps of the optocoupler 1d of the present invention.

With respect to this embodiment, the reflective structure 40, the transmission medium 50 and the isolation layer 60 used in the optocoupler 1d of the present invention may apply the same structural configuration with reference to any of the first to third embodiments described above. In addition, when the substrate 10 of the optocoupler 1d of the present invention adopts an undoped sapphire substrate, the concerned process of the aforementioned buffer layers 28 and 38 can be omitted.

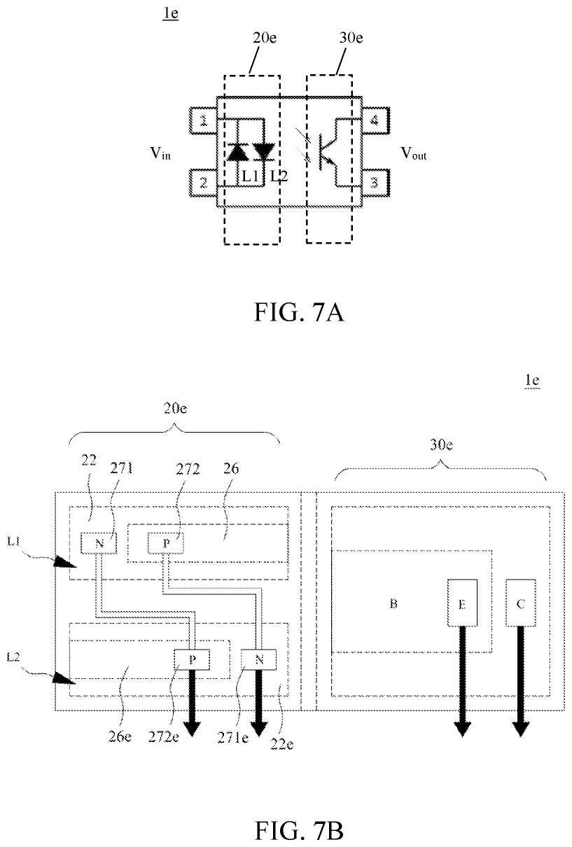

Please refer to FIG. 7A and FIG. 7B together. FIG. 7A is a schematic view of the sixth embodiment of the optocoupler of the present invention, and FIG. 7B is another schematic view of the sixth embodiment of the optocoupler of the present invention. It should be stated first, FIG. 7B simply shows the partial structure and circuit configuration of the sixth embodiment of the optocoupler of the present invention in a schematic top view, and the area separated by two parallel dotted lines in FIG. 7B represents electrical isolation. This embodiment is a structural modification of the first embodiment, and the difference lies in the change in the number of LED structures of the gallium nitride light emitter. As shown in FIG. 7A and FIG. 7B, in this embodiment, the gallium nitride light emitter 20e of the optocoupler 1e of the present invention includes a first LED structure L1 and a second LED structure L2, and the first LED structure L1 and the second LED structures L2 are connected in anti-parallel to each other. In this design, the N-type gallium nitride layer 22 of the first LED structure L1 is electrically connected to the electrical contact 272e of the transparent electrode 26e of the second LED structure L2 through the electrical contact 271, and the transparent electrode 26 of the first LED structure L1 is electrically connected to the electrical contact 271e of the N-type gallium nitride layer 22e of the second LED structure L2 through the electrical contact 272, and then they are electrically connected to external devices through the electrical contacts 271e and 272e, respectively. In this case, the input signal Vᵢₙ can be an AC signal so that the optocoupler 1e of the present invention is an optocoupler that is capable of reading an AC input driving current.

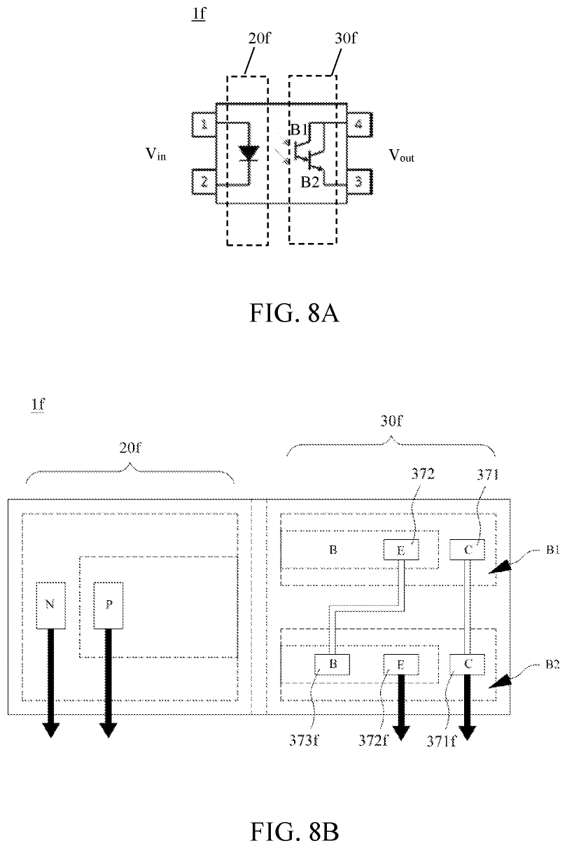

Please refer to FIG. 8A and FIG. 8B together. FIG. 8A is a schematic view of the seventh embodiment of the optocoupler of the present invention, and FIG. 8B is another schematic view of the seventh embodiment of the optocoupler of the present invention. It should be stated first, FIG. 8B simply shows the partial structure and circuit configuration of the seventh embodiment of the optocoupler of the present invention in a schematic top view, and the area separated by two parallel dotted lines in FIG. 8B represents electrical isolation. This embodiment is a structural modification example of the first embodiment, the difference lies in the change in the number of BJT structures of the gallium nitride light sensing switch. As shown in FIG. 8A and FIG. 8B, in this embodiment, the optocoupler if of the present invention includes a first BJT structure B1 and a second BJT structure B2, and the first BJT structure B1 and the second BJT structure B2 are connected in series to each other. In this design, the emitter of the first BJT structure B1 is electrically connected to the electrical contact 373f of the base of the second BJT structure B2 through the electrical contact 372, and the collector of the first BJT structure B1 is electrically connected to the electrical contact 371f of the collector of the second BJT structure B2 through the electrical contact 371, and they are electrically connected to external devices through the electrical contact 372f of the emitter and the electrical contact 371f of the collector of the second BJT structure B2, respectively. Therefore, the first BJT structure B1 and the second BJT structure B2 can produce a signal amplification effect on the output signal Vₒᵤₜ so that the optocoupler if of the present invention is an optocoupler that is capable of amplifying the output current.

The foregoing detailed description is illustrative in nature only and is not intended to limit the embodiments of the claimed subject matters or the applications or uses of such embodiments. Furthermore, while at least one exemplary embodiment has been presented in the foregoing detailed description, it should be appreciated that a wide variety of modifications to the present invention are possible. It should also be appreciated that the embodiments described herein are not intended to limit the scope, use, or configuration of the claimed subject matters in any way. Instead, the foregoing detailed description is intended to provide a person having ordinary skill in the art with a convenient guide for implementing one or more of the described embodiments. Moreover, various modifications may be made in the function and arrangement of the devices without departing from the scope defined by the claims, including known equivalents and any equivalents that may be anticipated at the time of filing this patent application.

What is claimed is:

1. An optocoupler, comprising:
a substrate;
a gallium nitride light emitter disposed on the substrate, being configured to emit a light signal according to an input signal;
a gallium nitride light sensing switch disposed on the substrate and electrically isolated from the gallium nitride light emitter, being configured to sense the light signal and generate an output signal according to the light signal;
a reflective structure, being configured to reflect the light signal; and
a transmission medium at least between the gallium nitride light emitter, the gallium nitride light sensing switch and the reflective structure;
wherein the light signal emitted from the gallium nitride light emitter is transmitted in the transmission medium, and is transmitted obliquely to the gallium nitride light sensing switch after being reflected by the reflective structure.

2. The optocoupler of claim 1, wherein the gallium nitride light emitter comprises at least one LED structure or at least one light emitting high electron mobility transistor structure.

3. The optocoupler of claim 2, wherein the gallium nitride light emitter comprises a first LED structure and a second LED structure, the first LED structure and the second LED structure are connected in anti-parallel to each other, and the input signal is an alternating current (AC) signal.

4. The optocoupler of claim 1, wherein the gallium nitride light sensing switch comprises at least one BJT structure or at least one high electron mobility transistor structure.

5. The optocoupler of claim 4, wherein the gallium nitride light sensing switch comprises a first BJT structure and a second BJT structure, and the first BJT structure and the second BJT structure are connected in series to each other to amplify the output signal.

6. The optocoupler of claim 1, wherein the transmission medium at least partially covers the gallium nitride light emitter and the gallium nitride light sensing switch, and the reflective structure is disposed on the transmission medium.

7. The optocoupler of claim 6, wherein the transmission medium is made of a packaging material or an insulating material having light transmission characteristics.

8. The optocoupler of claim 7, wherein the transmission medium is SiO₂, Si₃N₄ or epoxy resin.

9. The optocoupler of claim 1, further comprising a peripheral packaging structure, at least packaging the gallium nitride light emitter, the gallium nitride light sensing switch and the transmission medium, wherein the reflective structure is disposed on an inner surface of the peripheral packaging structure facing the gallium nitride light emitter and the gallium nitride light sensing switch.

10. The optocoupler of claim 9, wherein the transmission medium is air.

11. The optocoupler of claim 1, wherein the light signal emitted by the gallium nitride light emitter has a wavelength ranging between 300 nm and 500 nm.

12. The optocoupler of claim 1, wherein the substrate is a silicon substrate or a sapphire substrate.

13. The optocoupler of claim 12, further comprising a plurality of buffer layers, wherein when the substrate is the silicon substrate, the plurality of buffer layers are disposed between the gallium nitride light emitter and the substrate and between the gallium nitride light sensing switch and the substrate.
